(19) United States
(12) Patent Application Publication
(10) Pub. No.: US 2019/0325820 A1
(43) Pub. Date: Oct. 24, 2019

(54) DISPLAY PANEL DRIVING DEVICE AND DRIVING METHOD THEREOF

(71) Applicant: Raydium Semiconductor Corporation, Hsinchu (TW)

(72) Inventors: JUN-REN SHIH, Hsinchu City (TW); TZONG-YAU KU, Hsinchu City (TW); HSUEH-HAN LU, Hsinchu (TW)

(21) Appl. No.: 16/386,562

(22) Filed: Apr. 17, 2019

(30) Foreign Application Priority Data
Apr. 19, 2018 (TW) 107113384

(51) Int. Cl. G09G 3/3225; H01L 27/32

(52) U.S. Cl. CPC G09G 3/3225; G09G 2300/0809; G09G 2310/0286; H01L 27/3244

(57) ABSTRACT

A display panel driving device is configured to drive a display panel. The display panel driving device includes a driving unit, a digital circuit unit and a selecting unit. The driving unit includes a first channel and a second channel. The first channel includes a first amplifier, and the second channel comprises a second amplifier. The digital circuit unit is coupled to the driving unit, and configured to output a first signal and a second signal to the first channel and the second channel respectively. The selecting unit is coupled to the driving unit. When the first signal and the second signal are the same, the selecting unit optionally switches off the first amplifier or the second amplifier.

### RELATED APPLICATIONS

This application claims priority to Taiwan Application Serial Number 107113384, filed Apr. 19, 2018, which is herein incorporated by reference.

### BACKGROUND

### Technical Field

The present invention relates to a display panel driving device and a driving method therefor, specifically, in particular to a display panel driving device for output of a shared amplifier of a driving IC and a driving method therefor.

### Related Art

Generally, because voltages of a plurality of data lines need to be simultaneously driven, a plurality of analog amplifiers needs to be built in a thin film transistor liquid crystal display (TFT LCD) panel or an organic light-emitting display (OLED) panel.

For example, a Full HD panel has 1080*3=3240 data lines. When all the data lines emerge and are connected to a driving circuit, 3240 amplifiers need to be simultaneously started. If a low temperature poly-silicon (LTPS) panel is used as an example, and one to three multiplexers (MUX) are made of glass, a driving circuit has 1080 data lines for output. Therefore, 1080 amplifiers need to be simultaneously started.

For the foregoing panel, the time for a horizontal line is only 8.6 μs, and 1080 amplifiers need to perform output for three times. Therefore, rapid amplifiers are required, and the maximum of the output time can only be about ⅓of the time for the horizontal line. Rapid output requires rapid response of the amplifiers. Therefore, a large amount of DC current needs to be consumed. For example, a DC current of each IC is approximately 3 μA, and 1080 amplifiers need to consume approximately a DC current of 3 μA*1080=3.24 mA. Such power consumption is a serious problem for the driving circuit of the panel.

### SUMMARY

In view of this, an embodiment of the present invention provides a display panel driving device. Power consumption of a driving IC is reduced based on output of a shared amplifier of the driving IC.

In one embodiment, a display panel driving device is configured to drive a display panel, and includes a driving unit, a digital circuit unit, and a selecting unit. The driving unit includes a first channel and a second channel. The first channel includes a first amplifier, and the second channel includes a second amplifier. The digital circuit unit is coupled to the driving unit, and is configured to output a first signal and a second signal to the first channel and the second channel respectively. The selecting unit is coupled to the driving unit. When the first signal and the second signal are the same, the selecting unit optionally switches off the first amplifier or the second amplifier.

Another embodiment of the present invention provides a driving method for a display panel. Power consumption of a driving IC is reduced based on output of a shared amplifier of the driving IC.

In one embodiment, the driving method for a display panel includes the following steps: (S1) a digital circuit unit outputs a first signal and a second signal to a first amplifier and a second amplifier respectively; (S2) a selecting unit determines whether the first signal and the second signal are the same; (S3) when the first signal and the second signal are the same, the selecting unit optionally switches off the first amplifier; and (S4) the second amplifier outputs driving signals to a first output pad and a second output pad respectively.

Another embodiment of the present invention provides a driving method for a display panel. Power consumption of a driving IC is reduced based on output of a shared amplifier of the driving IC.

In one embodiment, the driving method for a display panel includes the following steps: (A1) a digital circuit unit outputs a first signal, a second signal, and a third signal to a first amplifier, a second amplifier, and a third amplifier respectively; (A2) a selecting unit determines whether the first signal, the second signal, and the third signal are the same; (A3) when the first signal, the second signal, and the third signal are the same, the selecting unit optionally switches off the first amplifier and the second amplifier; and (A4) the third amplifier outputs driving signals to a first output pad, a second output pad, and a third output pad.

Compared with the prior art, in the “DISPLAY PANEL DRIVING DEVICE AND DRIVING METHOD THEREOF” of one embodiment of the present invention, a concept of output of a shared amplifier of a driving IC is used, and whether an amplifier is shared for output is determined based on whether an input/output of the amplifier is the same, to reduce power consumption of the driving IC.

### BRIEF DESCRIPTION OF THE DRAWINGS

FIG. 1A is a schematic diagram of an embodiment of a display panel driving device according to the present invention;

FIG. 1B is a schematic diagram of an embodiment of a display panel driving device according to the present invention;

FIG. 1C is a schematic diagram of another embodiment of a display panel driving device according to the present invention;

FIG. 2A and FIG. 2B are schematic diagrams of another embodiment of a display panel driving device according to the present invention;

FIG. 2C is a schematic diagram of another embodiment of a display panel driving device according to the present invention;

FIG. 2D is a schematic diagram of another embodiment of a display panel driving device according to the present invention;

FIG. 3 is a flowchart of an embodiment of a driving method for a display panel according to the present invention; and

FIG. 4 is a flowchart of another embodiment of a driving method for a display panel according to the present invention.

### DETAILED DESCRIPTION

The following describes a plurality of implementations of the present invention with reference to figures and words. For clarity, practical details will be described in the following descriptions. However, it should be understood that the practical details are not intended to limit the present invention. In addition, to simplify the figures, some conventional structures and elements are schematically drawn in a simple manner in the figures.

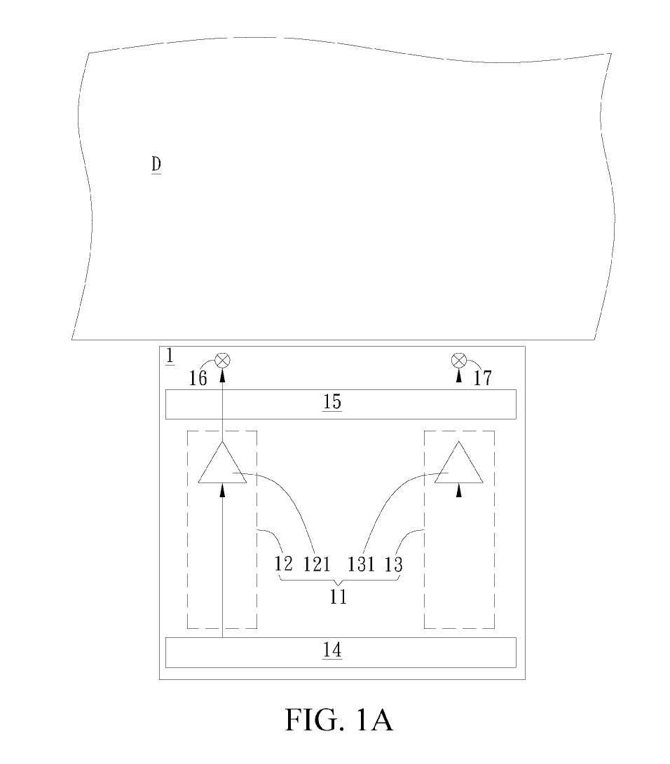

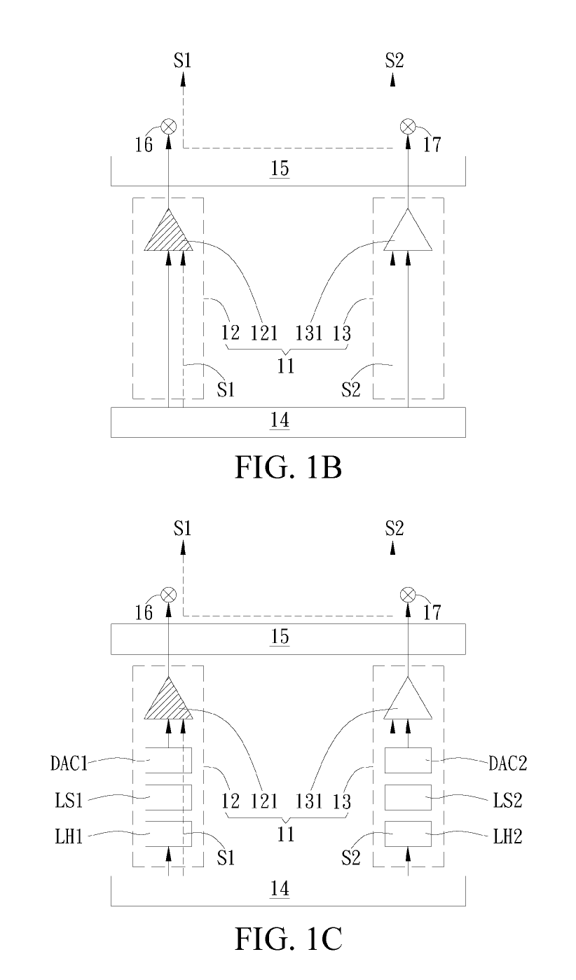

FIG. 1A is a schematic diagram of an embodiment of the present invention. A display panel driving device 1 is configured to drive a display panel D. The display panel driving device 1 preferably includes a driving unit 11, a digital circuit unit 14, and a selecting unit 15. The driving unit 11 preferably includes a first channel 12 and a second channel 13. In this embodiment, the first channel 12 includes a first amplifier 121, and the second channel 13 includes a second amplifier 131. The first amplifier 121 and the second amplifier 131 may be operational amplifiers (OP-Amp). The digital circuit unit 14 is coupled to the driving unit 11, and is configured to output a first signal and a second signal to the first channel and the second channel respectively. Specifically, the digital circuit unit 14 outputs the first signal and the second signal to the first amplifier 121 and the second amplifier 131 respectively. The selecting unit 15 is also coupled to the driving unit 11, and is preferably a switch circuit, but is not limited thereto. The selecting unit 15 is configured to switch signal output of the first amplifier 121 and the second amplifier 131.

The display panel driving device 1 further includes a first output pad 16 and a second output pad 17 that are coupled to the selecting unit 15, to transfer the signals to the display panel D.

For a transfer manner of the first signal and the second signal, refer to FIG. 1B. As shown in the figure, the digital circuit unit 14 inputs the first signal S1 and the second signal S2 to the first amplifier 121 inside the first channel 12 and the second amplifier 131 inside the second channel 13 respectively. The first signal S1 and the second signal S2 are digital signals. In this embodiment, the display panel driving device 1 may determine whether the first signal S1 and the second signal S2 are the same by using a controller, a microprocessor, or another similar device inside the display panel driving device 1. It should be noted that whether the first signal S1 and the second signal S2 are the same may be determined based on digital input code of the first signal S1 and the second signal S2. This is not limited thereto.

When determining that the first signal S1 and the second signal S2 are the same, the selecting unit 15 switches off one of the amplifiers. In this embodiment, the selecting unit 15 selects to switch off the first amplifier 121. Therefore, the first signal S1 that is originally output by the first amplifier 121 to the first output pad 16 is changed to be output by the second amplifier 131. That is, both the first signal S1 and the second signal S2 are output by the second amplifier 131. Further, the selecting unit 15 selects the second amplifier 131 to output the first signal S1 to the first output pad 16, and then the first output pad 16 transfers the first signal S1 to the display panel; and output the second signal S2 to the second output pad 17, and then the second output pad 17 transfers the second signal S2 to the display panel.

Accordingly, if a conventional panel having the same resolution is used as an example, because only one amplifier needs to be started in this embodiment, that is, a DC current of ½*1080*3 μA=1.62 mA, power consumption of the DC current may be reduced by a half.

It should be understood that if the first signal S1 is different from the second signal S2, an existing output manner is maintained. That is, the first signal S1 is output by the first amplifier 121, and the second signal S2 is output by the second amplifier 131.

It should be noted herein that the first signal S1 and the second signal S2 may be determined based on another determining basis in addition to the digital input code. As shown in an embodiment in FIG. 1C, a first channel 12 may further include a first digital-to-analog converter DAC1, a first level shifter LS1, or a first latch circuit LH1. That is, the determining basis may be an output value of the first digital-to-analog converter DAC1, an output value of the first level shifter LS1, or an output value of the first latch circuit LH1.

Similarly, a second channel 13 may include a second digital-to-analog converter DAC2, a second level shifter LS2, or a second latch circuit LH2. That is, the determining basis may be an output value of the second digital-to-analog converter DAC2, an output value of the second level shifter LS2, or an output value of the second latch circuit LH2.

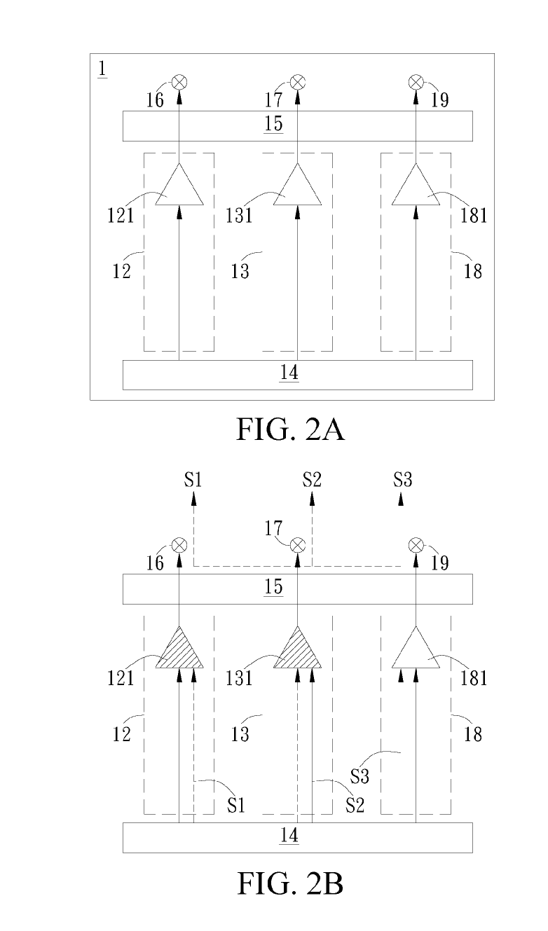

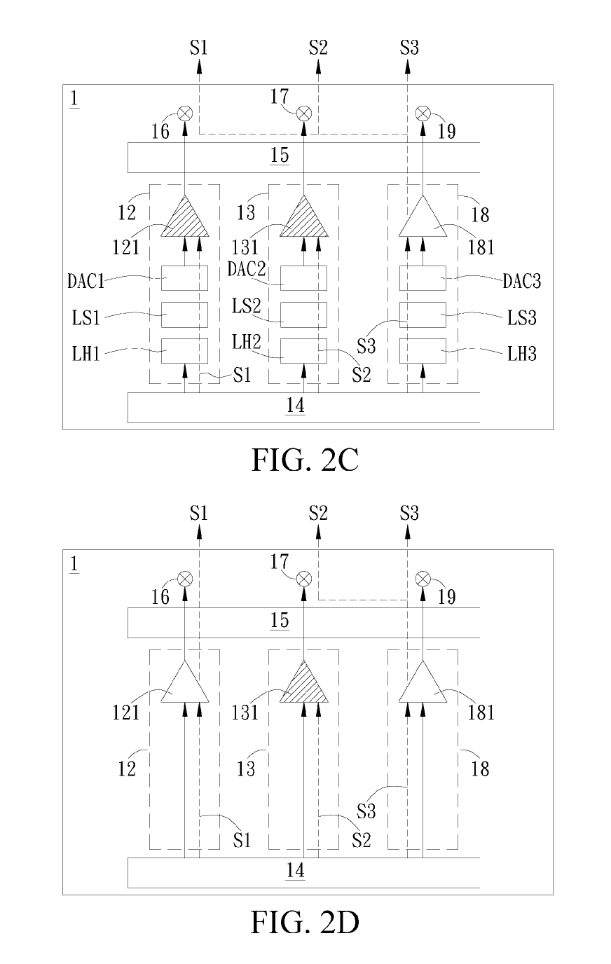

In another embodiment of the present invention, three channels are used as an example. Refer to FIG. 2A and FIG. 2B. As shown in the figures, a display panel driving device 1 preferably includes a driving unit 11, a digital circuit unit 14, a selecting unit 15, and a first output pad 16, a second output pad 17, and a third output pad 141 that are coupled to the selecting unit 15. The driving unit 11 preferably includes a first channel 12, a second channel 13, and a third channel 18. In this embodiment, the first channel 12 includes a first amplifier 121, the second channel 13 includes a second amplifier 131, and the third channel 18 includes a third amplifier 181. The first amplifier 121, the second amplifier 131, and the third amplifier 181 may be operational amplifiers (OP-Amp).

The digital circuit unit 14 is coupled to the driving unit 11, and is configured to output a first signal, a second signal, and a third signal to the first channel, the second channel, and the third channel respectively. Specifically, the digital circuit unit 14 outputs the first signal to the third signal to the first amplifier 121 to the third amplifier 181 respectively. The selecting unit 15 is also coupled to the driving unit 11, and is preferably a switch circuit, but is not limited thereto. The selecting unit 15 is configured to switch signal output of the first amplifier 121 to the third amplifier 181.

The digital circuit unit 14 inputs the first signal S1, the second signal S2, and the third signal S3 to the first amplifier 121 inside the first channel 12, the second amplifier 131 inside the second channel 13, and the third amplifier 181 inside the third channel 18 respectively. The first signal S1 to the third signal S3 are digital signals. In this embodiment, the display panel driving device 1 may determine whether the first signal S1, the second signal S2, and the third signal S3 are the same by using a controller, a microprocessor, or another similar device inside the display panel driving device 1. Similarly, whether the first signal S1, the second signal S2, and the third signal S3 are the same may be determined based on digital input code of the first signal S1 to the third signal S3. This is not limited thereto.

When determining that the first signal S1, the second signal S2, and the third signal S3 are the same, the selecting unit 15 switches off two of the amplifiers. In this embodiment, the selecting unit 15 selects to switch off the first amplifier 121 and the second amplifier 131. Therefore, the first signal S1 that is originally output by the first amplifier 121 to the first output pad 16 and the second signal S2 that is originally output by the second amplifier 131 to the second output pad 17 are changed to be output by the third amplifier 181. That is, the first signal S1, the second signal S2, and the third signal S3 are all output by the third amplifier 181. Further, the selecting unit 15 selects the third amplifier 181 to output the first signal S1 to the first output pad 16, and then the first output pad 16 transfers the first signal S1 to the display panel; output the second signal S2 to the second output pad 17, and then the second output pad 17 transfers the second signal S2 to the display panel; and output the third signal S3 to the third output pad 19, and then the third output pad 19 transfers the third signal S3 to the display panel.

Based on this design, if a conventional panel having the same resolution is used as an example, because only one amplifier needs to be started in this embodiment, that is, a DC current of ⅓*1080*3 μA=1.08 mA, ⅔of power consumption of the DC current may be reduced.

Similarly, the first signal S1, the second signal S2, and the third signal S3 may be determined based on another determining basis in addition to the digital input code. As shown in an embodiment in FIG. 2C, a third channel 18 may further include a third digital-to-analog converter DAC3, a third level shifter LS3, or a third latch circuit LH3. That is, the determining basis may be an output value of the third digital-to-analog converter DAC3, an output value of the third level shifter LS3, or an output value of the third latch circuit LH3.

For another embodiment of the present invention, refer to FIG. 2D. As shown in the figure, this embodiment mainly describes an action manner when input/output values of two of three amplifiers are the same. For example, when a second signal S2 is the same as a third signal S3 but is different from a first signal S1, that is, when S1≠S2=S3, the selecting unit 15 switches one of the second amplifier 131 or the third amplifier 181. In this embodiment, the selecting unit 15 selects to switch off the second amplifier 131. This is not limited thereto. Therefore, the second signal S2 that is originally output by the second amplifier 131 to the second output pad 17 is changed to be output by the third amplifier 181. That is, the first signal S1 is still output by the first amplifier 121, but both the second signal S2 and the third signal S3 are output by the third amplifier 181.

Further, the selecting unit 15 selects the third amplifier 181 to output the second signal S2 and the third signal S3 to the second output pad 17 and the third output pad 19 respectively, and then the second output pad 17 and the third output pad 19 transfer the second signal S2 and the third signal S3 respectively to the display panel; and the first signal S1 is still output by the first amplifier 121 to the first output pad 16, and then is transferred to the display panel. Based on this design, ⅓ of power consumption of a DC current may be reduced.

It should be noted that a person skilled in the art may apply, based on the foregoing embodiments, the display panel driving device to a situation in which there are N amplifiers.

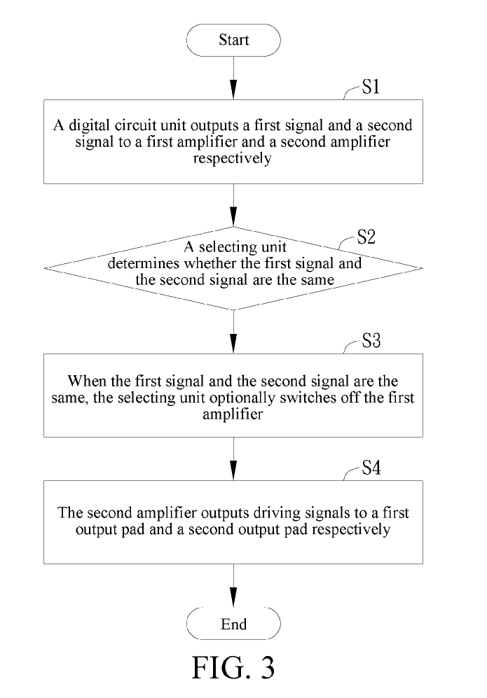

Another embodiment of the present invention provides a method applied to the foregoing embodiments. As shown in FIG. 3, this embodiment includes the following steps: (S1) a digital circuit unit outputs a first signal and a second signal to a first amplifier and a second amplifier respectively; (S2) a selecting unit determines whether the first signal and the second signal are the same; (S3) when the first signal and the second signal are the same, the selecting unit optionally switches off the first amplifier; and (S4) the second amplifier outputs driving signals to a first output pad and a second output pad respectively.

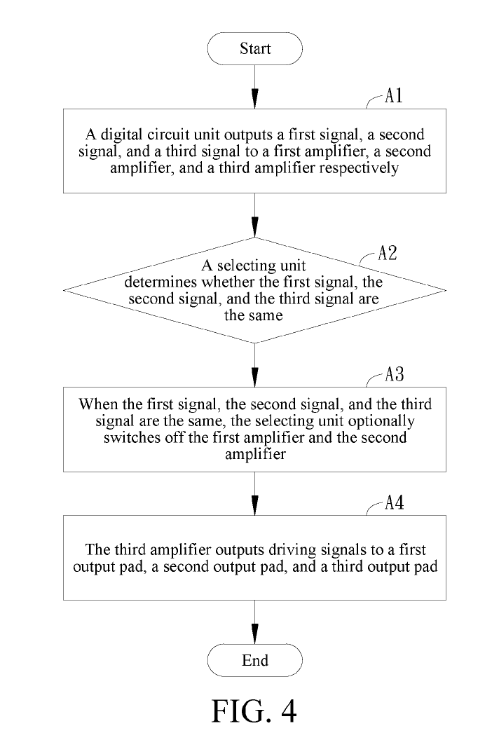

FIG. 4 shows another embodiment of the present invention, This embodiment includes the following steps: (A1) a digital circuit unit outputs a first signal, a second signal, and a third signal to a first amplifier, a second amplifier, and a third amplifier respectively; (A2) a selecting unit determines whether the first signal, the second signal, and the third signal are the same; (A3) when the first signal, the second signal, and the third signal are the same, the selecting unit optionally switches off the first amplifier and the second amplifier; and (A4) the third amplifier outputs driving signals to a first output pad, a second output pad, and a third output pad.

For the embodiments in FIG. 3 and FIG. 4, a circuit configuration and an action manner are described in detail in the foregoing embodiments. Details are not described herein.

Compared with the prior art, in the “DISPLAY PANEL DRIVING DEVICE AND DRIVING METHOD THEREOF” of the present invention, a concept of output of a shared amplifier of a driving IC is used, and whether an amplifier is shared for output is determined based on whether an input/output of the amplifier is the same, to reduce power consumption of the driving IC.

The foregoing specific embodiments are described in detail to more clearly describe features and the spirit of the present invention rather than limit the scope of the present invention. A person skilled in the art may make various alternations and modifications without departing from the sprit and scope of the present invention. Therefore, the protection scope of the present invention shall be subject to the scope defined by the appended claims.

### SYMBOL DESCRIPTION

11 Driving unit

12 First channel

13 Second channel

14 Digital circuit unit

15 Selecting unit

16 First output pad

17 Second output pad

18 Third channel

121 First amplifier

131 Second amplifier

181 Third amplifier

19 Third output pad

S1 First signal

S2 Second signal

S3 Third signal

DAC1 First digital-to-analog converter

DAC2 Second digital-to-analog converter

DAC3 Third digital-to-analog converter

LS1 First level shifter

LS2 Second level shifter

LS3 Third level shifter

LH1 First latch circuit

LH2 Second latch circuit

LH3 Third latch circuit

What is claimed is:

1. A display panel driving device, configured to drive a display panel, wherein the display panel driving device comprises:
a driving unit, comprising:
a first channel, comprising a first amplifier; and
a second channel, comprising a second amplifier;
a digital circuit unit, coupled to the driving unit, and configured to output a first signal and a second signal to the first channel and the second channel respectively; and
a selecting unit, coupled to the driving unit, wherein when the first signal and the second signal are the same, the selecting unit optionally switches off the first amplifier or the second amplifier.

2. The display panel driving device according to claim 1, further comprising a first output pad and a second output pad, coupled to the selecting unit.

3. The display panel driving device according to claim 2, wherein when the selecting unit switches off the first amplifier, the driving unit outputs driving signals to the first output pad and the second output pad respectively by using the second amplifier.

4. The display panel driving device according to claim 1, wherein the first channel further comprises a first digital-to-analog converter, a first level shifter, or a first latch circuit.

5. The display panel driving device according to claim 1, wherein the second channel further comprises a second digital-to-analog converter, a second level shifter, or a second latch circuit.

6. The display panel driving device according to claim 1, wherein the driving unit further comprises a third channel, the third channel comprises a third amplifier, and the digital circuit unit inputs a third signal to the third channel; and
when the first signal, the second signal, and the third signal are the same, the selecting unit optionally switches off the first amplifier and the second amplifier.

7. The display panel driving device according to claim 6, further comprising a third output pad, coupled to the selecting unit.

8. The display panel driving device according to claim 7, wherein when the selecting unit switches off the first amplifier and the second amplifier, the driving unit outputs driving signals to the first output pad, the second output pad, and the third output pad respectively by using the third amplifier.

9. The display panel driving device according to claim 6, wherein the third channel further comprises a third digital-to-analog converter, a third level shifter, or a third latch circuit.

10. A driving method for a display panel, comprising the following steps:
(S1) a digital circuit unit outputs a first signal and a second signal to a first amplifier and a second amplifier respectively;
(S2) a selecting unit determines whether the first signal and the second signal are the same;
(S3) when the first signal and the second signal are the same, the selecting unit optionally switches off the first amplifier; and
(S4) the second amplifier outputs driving signals to a first output pad and a second output pad respectively.

11. The method according to claim 10, wherein the first output pad is coupled to the first amplifier, and the second output pad is coupled to the second amplifier.

12. A driving method for a display panel, comprising the following steps:
(A1) a digital circuit unit outputs a first signal, a second signal, and a third signal to a first amplifier, a second amplifier, and a third amplifier respectively;
(A2) a selecting unit determines whether the first signal, the second signal, and the third signal are the same;
(A3) when the first signal, the second signal, and the third signal are the same, the selecting unit optionally switches off the first amplifier and the second amplifier; and
(A4) the third amplifier outputs driving signals to a first output pad, a second output pad, and a third output pad respectively.

13. The method according to claim 12, wherein the first output pad is coupled to the first amplifier, the second output pad is coupled to the second amplifier, and the third output pad is coupled to the third amplifier.
